(19) United States
(12) Patent Application Publication
(10) Pub. No.: US 2014/0060613 A1
(43) Pub. Date: Mar. 6, 2014

(54) METHOD AND APPARATUS FOR INTEGRATING AN INFRARED (IR) PHOTOVOLTAIC CELL ON A THIN FILM PHOTOVOLTAIC CELL

(71) Applicants: Franky SO, Gainesville, FL (US); Do Young Kim, Gainesville, FL (US); Bhabendra K. Pradhan, Gainesville, FL (US)

(72) Inventors: Franky SO, Gainesville, FL (US); Do Young Kim, Gainesville, FL (US); Bhabendra K. Pradhan, Gainesville, FL (US)

(73) Assignees: NANOHOLDINGS, LLC, Rowayton, CT (US); UNIVERSITY OF FLORIDA RESEARCH FOUNDATION, INC., Gainesville, FL (US)

(21) Appl. No.: 14/009,945

(22) PCT Filed: Apr. 3, 2012
(86) PCT No.: PCT/US2012/031988

§ 371 Date: Nov. 18, 2013

Related U.S. Application Data
(60) Provisional application No. 61/472,071, filed on Apr. 5, 2011.

(51) Int. Cl. H01L 31/0687

(52) U.S. Cl. CPC H01L 31/0687
USPC 136/244; 438/80

(57) ABSTRACT

Embodiments of the subject invention relate to solar panels, methods of fabricating solar panels, and methods of using solar panels to capture and store solar energy. An embodiment of a solar panel can include a photovoltaic cell that is sensitive to visible light and an infrared photovoltaic cell that is sensitive to light having a wavelength of greater than 0.70 μm.

### CROSS REFERENCE TO RELATED APPLICATION

The present application claims the benefit of U.S. Provisional Application Ser. No. 61/472,071, filed Apr. 5, 2011, the disclosure of which is hereby incorporated by reference herein in its entirety, including any figures, tables, or drawings.

### BACKGROUND OF IN

Photovoltaic cells are considered an important source of renewable energy for helping to solve the world's energy shortage today. Various photovoltaic cell technologies have been developed, and thin film photovoltaic cells such as copper indium gallium selenide (GIGS) and CdTe have received attention because of their compatibility with large area manufacturing. While these thin film photovoltaic technologies have reported power conversion efficiencies of about 20% resulting from an external quantum efficiency of more than 90% at visible wavelengths, these thin film photovoltaic cells have no sensitivity for radiation with at a wavelength above 1 μm.

### BRIEF SUMMARY

Embodiments of the subject invention relate to novel and advantageous solar panels, as well as methods of manufacturing the solar panels and method of using the solar panels. The solar panels and methods of use thereof can advantageously capture and store solar energy from a wider spectrum of photons than conventional photovoltaic cells.

In an embodiment, a solar panel can include: a first photovoltaic cell, wherein the first photovoltaic cell is sensitive to photons having a first one or more wavelengths, wherein the first one or more wavelengths are in a first wavelength range; and a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. In a further embodiment, the at least one of the second one or more wavelengths can be at least 700 nm.

In another embodiment of the present invention, a method of fabricating a solar panel can include: forming a first photovoltaic cell, wherein the first photovoltaic cell is sensitive to photons having a first one or more wavelengths, wherein the first one or more wavelengths are in a first wavelength range; forming a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. The method can further comprise coupling the first photovoltaic cell and the second photovoltaic cell. In a further embodiment, the at least one of the second one or more wavelengths can be at least 700 nm.

In a further embodiment, a method of capturing and storing solar energy can include positioning a solar panel such that sunlight is incident on the solar panel, wherein the solar panel includes: a first photovoltaic cell, wherein the first photovoltaic cell is sensitive to photons having a first one or more wavelengths, wherein the first one or more wavelengths are in a first wavelength range; and a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. In a further embodiment, the at least one of the second one or more wavelengths can be at least 700 nm.

### BRIEF DESCRIPTION OF DRAWINGS

FIG. 1A shows the theoretical maximum of the short circuit current density (J_{SC}) and the power conversion efficiency (PCE) of an embodiment of the subject invention.

FIG. 1B shows the absorbance spectra of PbS nanocrystals with various sizes, and the inset shows the absorption coefficient spectrum and TEM image of 50 nm thick PbSe quantum dot film with 1.3 μm peak wavelength.

FIG. 2A shows a cross-section of a solar panel according to an embodiment of the subject invention.

FIG. 2B shows a cross-section of a solar panel according to another embodiment of the subject invention.

### DETAILED DISCLOSURE

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present. When the term “directly on” is used herein, when referring to layers, regions, patterns, or structures, it is understood that the layer, region, pattern or structure is directly on another layer or structure, such that no intervening layers, regions, patterns, or structures are present.

When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

When the term “sensitive” is used herein, in conjunction with describing a photovoltaic cell being sensitive to a certain type of light or to photons having a wavelength of a given value or within a given range, it is understood that the photovoltaic cell is capable of absorbing the light to which it is sensitive and generating a carrier. When the Won “not sensitive” or “insensitive” is used herein, in conjunction with describing a photovoltaic cell not being sensitive or being insensitive to a certain type of light or to photons having a wavelength of a given value or within a given range, it is understood that the photovoltaic cell is not able to absorb the light to which it is not sensitive and cannot generate a carrier from the absorption of the light.

It is to be understood that by “transparent,” it is meant that at least a portion of the light to which an object is said to be transparent can pass through the object without being absorbed or reflected.

Embodiments of the subject invention relate to novel and advantageous solar panels, as well as methods of manufacturing the solar panels and method of using the solar panels. The solar panels and methods of use thereof can advantageously capture and store solar energy from a wider spectrum of photons than conventional photovoltaic cells.

In an embodiment, a solar panel can include: a first photovoltaic cell, wherein the first photovoltaic cell is sensitive to photons having a first one or more wavelengths, wherein the first one or more wavelengths are in a first wavelength range; and a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. In a further embodiment, the at least one of the second one or more wavelengths can be at least 700 nm.

In another embodiment of the present invention, a method of fabricating a solar panel can include: forming a first photovoltaic cell, wherein the first photovoltaic cell is sensitive to photons having a first one or more wavelengths, wherein the first one or more wavelengths are in a first wavelength rang; forming a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. The method can further comprise coupling the first photovoltaic cell and the second photovoltaic cell. In a further embodiment, the at least one of the second one or more wavelengths can be at least 700 nm.

In a further embodiment, a method of capturing and storing solar energy can include positioning a solar panel such that sunlight is incident on the solar panel, wherein the solar panel includes: a first photovoltaic cell, wherein the first photovoltaic cell is sensitive to photons having a first one or more wavelengths, wherein the first one or more wavelengths are in a first wavelength rang; and a second photovoltaic cell, wherein the second photovoltaic cell is sensitive to photons having a second one or more wavelengths, wherein the second one or more wavelengths are in a second wavelength range, such that at least one of the second one or more wavelengths is not in the first wavelength range, and at least one of the first one or more wavelengths is not in the second wavelength range. At least one of the second one or more wavelengths can be greater than 1 μm. In a further embodiment, the at least one of the second one or more wavelengths can be at least 700 nm.

Embodiments of the subject invention relate to a method and apparatus for providing a novel solar panel structure harvesting photons from the visible range up to the infrared range in the solar spectrum by integrating an IR photovoltaic cell on a photovoltaic cell, such as a conventional thin film photovoltaic cell. While the solar spectrum ranges from 350 nm to 2500 nm, conventional thin film photovoltaic cells have no infrared sensitivity beyond 1 μm. That is, related art photovoltaic cells are not sensitive to photons having wavelengths greater than 1 μm and cannot capture and/or store energy from such photons. As is known in the art, the visible range of the spectrum is from 380 nm to 750 nm, inclusive.

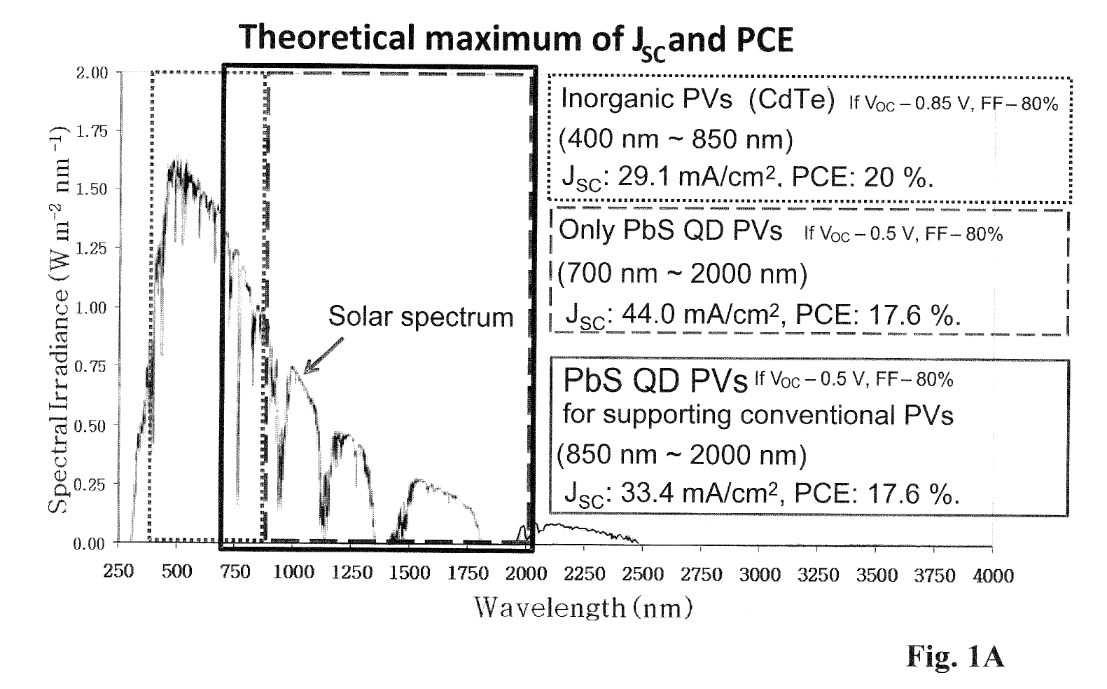

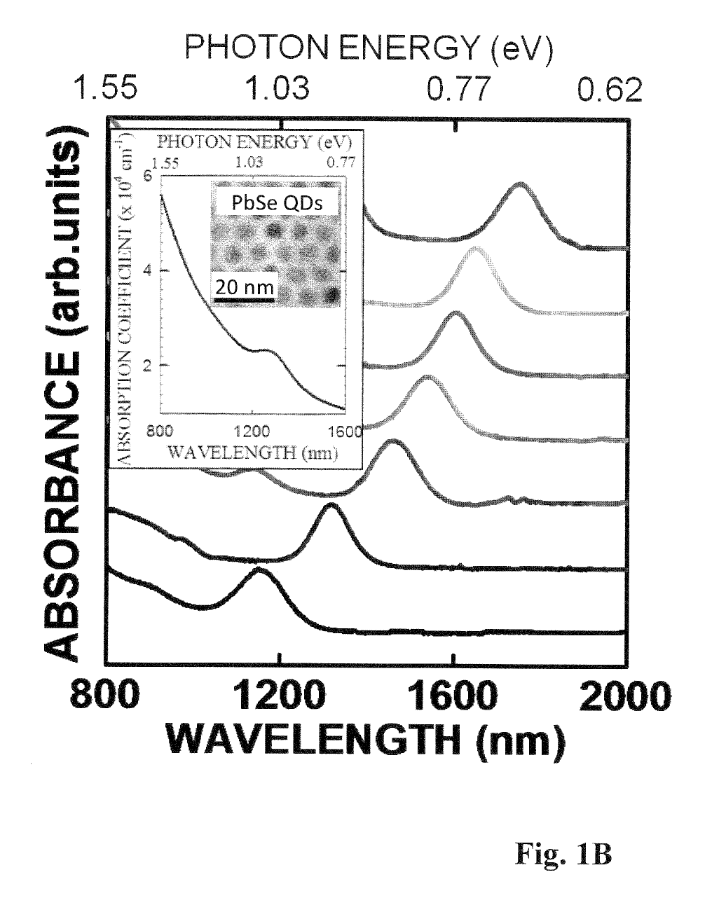

Referring to FIG. 1A, a solar panel according to an embodiment of the subject invention can result in an increased power conversion efficiency (PCE). FIG. 1A shows spectral irradiance (W/m²nm) vs. wavelength (nm) of the incident light. For an inorganic photovoltaic cell (for example, including CdTe), which is sensitive to light having a wavelength in the range of from about 400 nm to about 850 nm, if all the photons in the range of from about 400 nm to about 850 nm are converted to the carriers, J_{SC} is 29.1 mA/cm² and if V_{OC} is 0.85 V and the fill factor (FF) is 80%, PCE is 20%. For an IR photovoltaic cell including PbS quantum dots and sensitive to light having a wavelength in the range of from about 700 nm to about 2000 nm, if all the photons in the range of from about 700 nm to about 2000 nm are converted to the carriers, J_{SC} is 44.0 mA/cm² and if V_{OC} is 0.5 V and FF is 80%, is 17.6%. For an IR photovoltaic cell including PbS quantum dots and sensitive to light having a wavelength in the range of from about 850 nm to about 2000 nm, if all the photons in the range of from about 850 nm to about 2000 nm are converted to the carriers, J_{SC} is 33.4 mA/cm² and if V_{OC} is 0.5 V and FF is 80%, PCE is 13.4%.

Infrared photodetectors using solution-processable nanocrystals (e.g., PbS or PbSe nanocrystals) have been described in U.S. patent application Ser. No. 13/272,995 (filed Oct. 13, 2011), which claims priority to U.S. Provisional Patent Application Ser. No. 61/416,630 (filed Nov. 23, 2010), the disclosures of both of which are hereby incorporated by reference in their entirety. Such IR photodetectors have been shown to be compatible with large area manufacturing. In embodiments of the subject invention, an IR photovoltaic cell can have a structure similar to that of the infrared photodetector described in U.S. patent application Ser. No. 13/272,995, which claims priority to U.S. Provisional Patent Application Ser. No. 61/416,630, and/or similar to that of the infrared photodetector described in U.S. Provisional Patent Application Ser. No. 61/416,630. Also, referring to FIG. 1B, which shows the absorbance of PbSe quantum dots, PbSe quantum dots have infrared sensitivity.

When an IR photovoltaic cell is integrated on a photovoltaic cell (such as a conventional thin film photovoltaic cell), a high efficiency photovoltaic panel can be realized.

Embodiments of the subject invention relate to novel photovoltaic panels for harvesting a large portion of the solar spectrum by integrating an IR photovoltaic cell on a photovoltaic cell (such as a conventional thin film photovoltaic cell). In some embodiments, a photovoltaic panel can harvest the entire solar spectrum.

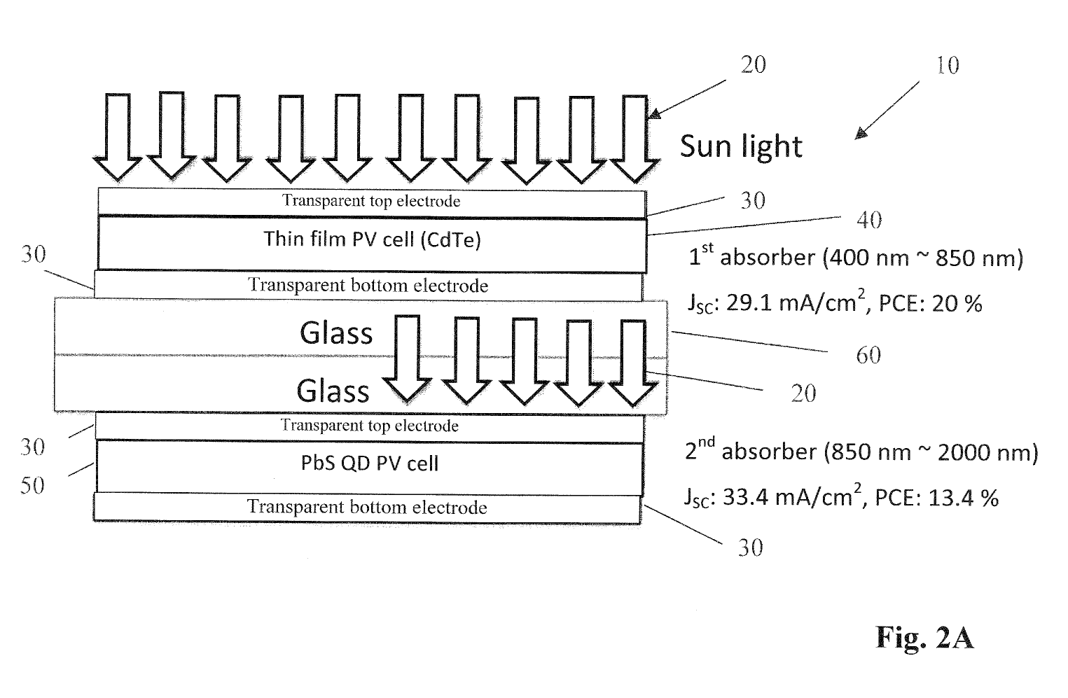

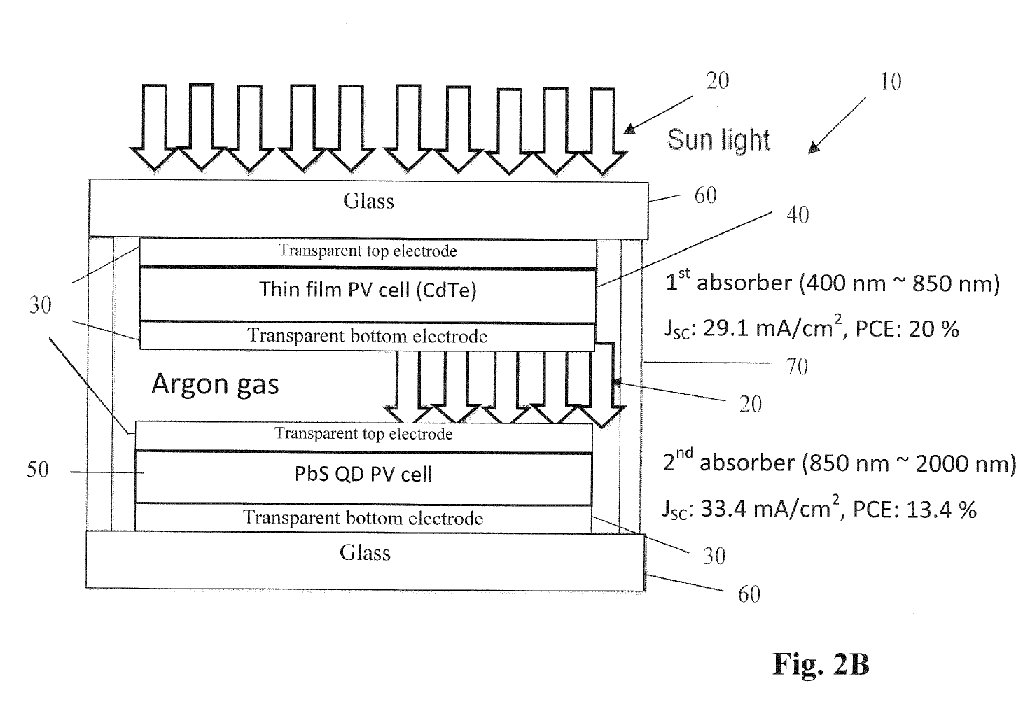

Referring to FIG. 2A, in an embodiment of the subject invention, a solar panel 10 can include a photovoltaic cell 40 and an IR photovoltaic cell 50. The photovoltaic cell 40 can be, for example, a thin film photovoltaic cell and can include cadmium telluride (CdTe), copper indium gallium selenide (CIGS), amorphous silicon (a-Si), and/or polysilicon (poly-Si), though embodiments are not limited thereto. In many embodiments, the photovoltaic cell 40 is not sensitive to photons having a wavelength greater than 1 μm. For example, the photovoltaic cell 40 can be sensitive to photons in the visible range. In one embodiment, the photovoltaic cell 40 can be sensitive to photons having a wavelength of from about 400 nm to about 850 nm.

The IR photovoltaic cell 50 is sensitive to photons having a wavelength greater than 1 μm. In an embodiment, the IR photovoltaic cell 50 is sensitive to photons having a wavelength up to 2500 nm. In another embodiment, the IR photovoltaic cell 50 is sensitive to photons having a wavelength up to about 2000 nm. In a further embodiment, the IR photovoltaic cell 50 is sensitive to photons having a wavelength up to 2000 nm. In yet a further embodiment, the IR photovoltaic cell 50 is sensitive to photons having a wavelength in a range of from about 850 nm to about 2000 nm.

It is to be understood that, in this description and in the appended claims, when a photovoltaic cell 40 or IR photovoltaic cell 50 is described as sensitive to photons having a wavelength of a given value, in a given range, or of at least a certain value, this does not preclude the photovoltaic cell 40 or IR photovoltaic cell 50 from being sensitive to photons having a wavelength different from the given value, outside the given range, or of less than the certain value, unless explicitly stated. That is, in this description and in the appended claims, when a photovoltaic cell 40 or IR photovoltaic cell 50 is described as sensitive to photons having a wavelength of a given value, in a given range, or of at least a certain value, the photovoltaic cell 40 or IR photovoltaic cell 50 is sensitive to at least those photons and may or may not also be sensitive to photons having a wavelength different from the given value, outside the given range, or of less than the certain value, unless it is explicitly stated that the photovoltaic cell 40 or IR photovoltaic cell 50 is only sensitive to photons having the stated value or in the stated range or that the photovoltaic cell 40 or IR photovoltaic cell 50 is not sensitive to photons having a given value, within a given range, or greater than a certain value.

In various embodiments, the IR photovoltaic cell 50 can be sensitive to photons having a wavelength of at least any of the following values (all values are in μm): 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, 0.50, 0.51, 0.52, 0.53, 0.54, 0.55, 0.56, 0.57, 0.58, 0.59, 0.60, 0.61, 0.62, 0.63, 0.64, 0.65, 0.66, 0.67, 0.68, 0.69, 0.70, 0.71, 0.72, 0.73, 0.74, 0.75, 0.76, 0.77, 0.78, 0.79, 0.80, 0.81, 0.82, 0.83, 0.84, 0.85, 0.86, 0.87, 0.88, 0.89, 0.90, 0.91, 0.92, 0.93, 0.94, 0.95, 0.96, 0.97, 098, 0.99, 1.00, 1.01, 1.02, 1.03, 1.04, 1.05, 1.06, 1.07, 1.08, 1.09, 1.10, 1.11, 1.12, 1.13, 1.14, 1.15, 1.16, 1.17, 1.18, 1.19, 1.20, 1.21, 1.22, 1.23, 1.24, 1.25, 1.26, 1.27, 1.28, 1.29, 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58 ,1.59, 1.60, 1.61, 1.62, 1.63, 1.64, 1.65, 1.66, 1.67, 1.68, 1.69, 1.70, 1.71, 1.72, 1.73, 1.74, 1.75, 1.76, 1.77, 1.78, 1.79, 1.80, 1.81, 1.82, 1.83, 1.84, 1.85, 1.86, 1.87, 1.88, 1.89, 1.90, 1.91, 1.92, 1.93, 1.94, 1.95, 1.96, 1.97, 1.98, or 1.99 (i.e., the IR photovoltaic cell 50 can he sensitive to photons having a wavelength of: at least 0.20 μm, at least 0.21 μm, . . . , at least 1.99 μm). In further embodiments, the IR photovoltaic cell 50 can he sensitive to only those photons having a wavelength of at least any of the following values (all values are in μm), while not being sensitive to any photons having a wavelength of less than the value: 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, 0.50, 0.51, 0.52, 0.53, 0.54, 0.55, 0.56, 0.57, 0.58, 0.59, 0.60, 0.61, 0.62, 0.63, 0.64, 0.65, 0.66, 0.67, 0.68, 0.69, 0.70, 0.71, 0.72, 0.73, 0.74, 0.75, 0.76, 0.77, 0.78, 0.79, 0.80, 0.81, 0.82, 0.83, 0.84, 0.85, 0.86, 0.87, 0.88, 0.89, 0.90, 0.91, 0.92, 0.93, 0.94, 0.95, 0.96, 0.97, 098, 0.99, 1.00, 1.01, 1.02, 1.03, 1.04, 1.05, 1.06, 1.07, 1.08, 1.09, 1.10, 1.11, 1.12, 1.13, 1.14, 1.15, 1.16, 1.17, 1.18, 1.19, 1.20, 1.21, 1.22, 1.23, 1.24, 1.25, 1.26, 1.27, 1.28, 1.29, 1.30, 1.31, 1.32, 1.33, 1.34, 1.35, 1.36, 1.37, 1.38, 1.39, 1.40, 1.41, 1.42, 1.43, 1.44, 1.45, 1.46, 1.47, 1.48, 1.49, 1.50, 1.51, 1.52, 1.53, 1.54, 1.55, 1.56, 1.57, 1.58 ,1.59, 1.60, 1.61, 1.62, 1.63, 1.64, 1.65, 1.66, 1.67, 1.68, 1.69, 1.70, 1.71, 1.72, 1.73, 1.74, 1.75, 1.76, 1.77, 1.78, 1.79, 1.80, 1.81, 1.82, 1.83, 1.84, 1.85, 1.86, 1.87, 1.88, 1.89, 1.90, 1.91, 1.92, 1.93, 1.94, 1.95, 1.96, 1.97, 1.98, or 1.99 (i.e. the IR photovoltaic cell 50 can be sensitive to only those photons having a wavelength of: at least 0.20 μm, at least 0.21 μm, . . . , at least 1.99 μm; while not being sensitive to any photons having a wavelength of less than 0.20 μm, 0.21 μm, . . . , 1.99 μm, respectively). In a preferred embodiment, the IR photovoltaic cell 50 is sensitive to photons having a wavelength of greater than 1 micron. In another preferred embodiment, the IR photovoltaic cell 50 is sensitive to photons having a wavelength of at least 0.70 microns. In yet another preferred embodiment, the IR photovoltaic cell 50 is sensitive to photons having a wavelength of at least 0.85 microns.

In certain embodiments, the IR photovoltaic cell 50 can include an IR sensitizing layer including quantum dots. The quantum dots can be, for example, PbS or PbSe quantum dots, though embodiments are not limited thereto.

In many embodiments, the solar panel 10 can include a electrode 30 on one or both sides of the photovoltaic cell 40 and/or the IR photovoltaic cell 50. In one embodiment, both the photovoltaic cell 40 and the IR photovoltaic cell 50 include a transparent anode and a transparent cathode. Each electrode layer 30 can be any transparent electrode known in the art, for example, a layer including indium tin oxide (ITO), carbon nanotubes (CNTs), indium zinc oxide (IZO), a silver nanowire, and/or a magnesium:silver/Alq3 (Mg:Ag/Alq3) stack layer. Each electrode layer 30 can include a transparent conductive oxide (TCO), including a TCO other than those explicitly listed herein. In a specific embodiment, one or more of the transparent electrode layers can be a Mg:Ag/Alq3 stack layer such that the Mg:Ag layer has a ratio of 10:1 (Mg:Ag). The Mg:Ag layer can have a thickness of less than 30 nm, and the Alq3 layer can have a thickness of from 0 nm to 200 nm. Each electrode layer 30 can be transparent to at least a portion of the light in the visible region of the spectrum. Each electrode layer 30 can be transparent to at least a portion, and preferably all, of the light in the infrared region of the spectrum. In certain embodiments, each electrode layer 30 can be transparent to at least a portion, and preferably all, of the light in the visible region of the spectrum and at least a portion, and preferably all, of the light in the infrared region of the spectrum. In an embodiment, the solar panel 10 can include a glass substrate 60 between the photovoltaic cell 40 and the IR photovoltaic cell 50. For example, the IR photovoltaic cell 50 can be fabricated on the glass substrate 60, and then the glass substrate 60 can be coupled onto the photovoltaic cell 40 which may also include a glass substrate 60.

Referring to FIG. 2B, in another embodiment, the solar panel 10 can use a structure that positions argon gas in between the photovoltaic cell 40 and the IR photovoltaic cell 50 such that the light exiting the photovoltaic cell 40 passes through the argon gas before entering the IR photovoltaic cell 50. A specific embodiment utilizes a chamber 70 housing argon gas. The photovoltaic cell 40 and the IR photovoltaic cell 50 can both be partially, or entirely, positioned within the chamber 70 and/or can form a part of the chamber 70. For example, the photovoltaic cell 40 and the IR photovoltaic cell 50 can each optionally include a glass substrate 60, and the glass substrate 60 of the photovoltaic cell 40 can serve as a top or bottom of the chamber 70 with the glass substrate 60 of the IR photovoltaic cell 50 also serving as a top or bottom of the chamber 70.The solar panels 10 in accordance with specific embodiments of the subject invention can be configured such that incident sunlight 20 is incident upon both the photovoltaic cell 40 and the IR photovoltaic cell 50 and at least a portion of the sunlight 20 is absorbed by the photovoltaic cell 40 and at least a portion of the sunlight 20 is absorbed by the IR photovoltaic cell 50. Such configurations are shown in FIGS. 2A and 2B in which the sunlight 20 is incident upon the photovoltaic cell 40 and is incident upon the IR photovoltaic cell 50 after passing through the (optional) glass substrate(s) 60 (in FIG. 2A) or the argon gas (in FIG. 2B).

Though the electrode layers 30 are labeled in FIGS. 2A and 2B as transparent, embodiments are not limited thereto. That is, each electrode layer 30 can be transparent to at least a portion of visible light and/or at least a portion of IR light but may not be transparent to at least a portion of visible light and/or at least a portion of IR light.

In an embodiment, the top electrode 30 of the photovoltaic cell 40 can he an anode or a cathode and is transparent to at least a portion of visible light and at least a portion of IR light. The bottom electrode 30 of the photovoltaic cell 40 can be an anode or a cathode and is transparent to at least a portion of IR light and may be transparent to at least a portion of visible light. The top electrode 30 of the IR photovoltaic cell 50 can be an anode or a cathode and is transparent to at least a portion of IR light and may be transparent to at least a portion of visible light. The bottom electrode 30 of the IR photovoltaic cell 50 can be an anode or a cathode and may be transparent to at least a portion of IR light and may be transparent to at least a portion of visible light.

In certain embodiments, the solar panel 10 can be operated in “upside down” mode such that light is incident on the bottom electrode 30 of the IR photovoltaic cell 50. In a particular embodiment, the bottom electrode 30 of the IR photovoltaic cell 50 can be an anode or a cathode and is transparent to at least a portion of visible light and at least a portion of IR light. The top electrode 30 of the IR photovoltaic cell 50 can be an anode or a cathode and is transparent to at least a portion of visible and may be transparent to at least a portion of IR light. The bottom electrode 30 of the photovoltaic cell 40 can be an anode or a cathode and is transparent to at least a portion of visible light and may be transparent to at least a portion of IR light. The top electrode 30 of the photovoltaic cell 40 can be an anode or a cathode and may be transparent to at least a portion of IR light and may be transparent to at least a portion of visible light.

In many embodiments, the solar panel 10 can be configured such that light incident on an input surface of the photovoltaic cell 40, which passes through the photovoltaic cell 40 and exits an output surface of the first photovoltaic cell 40, is incident on an input surface of the IR photovoltaic cell 50 and enters the IR photovoltaic cell 50. In another embodiment, the solar panel 10 can be configured such that light incident on an input surface of the IR photovoltaic cell 50, which passes through the IR photovoltaic cell 50 and exits an output surface of the IR photovoltaic cell 50, is incident on an input surface of the photovoltaic cell 40 and enters the photovoltaic cell 40.

In one embodiment of the subject invention, a method of capturing and storing solar energy can include positioning a solar panel such that sunlight is incident on the solar panel, wherein the solar panel includes: a photovoltaic cell, wherein the photovoltaic cell is sensitive to photons having a wavelength in the visible range; and an infrared photovoltaic cell, wherein the infrared photovoltaic cell is sensitive to photons having a wavelength greater than 1 μm. The solar panel can be as described herein with reference to FIGS. 2A and 2B. In many embodiments, the photovoltaic cell is not sensitive to photons having a wavelength greater than 1 μm. For example, the photovoltaic cell can be sensitive to photons in the visible range. In one embodiment, the photovoltaic cell can be sensitive to photons having a wavelength of from about 400 nm to about 850 nm.

In many embodiments, light incident on an input surface of the photovoltaic cell 40 can pass through the photovoltaic cell 40 and exit an output surface of the first photovoltaic cell 40, and can then be incident on an input surface of the IR photovoltaic cell 50 and enter the IR photovoltaic cell 50. In another embodiment, light incident on an input surface of the

IR photovoltaic cell 50 can pass through the IR photovoltaic cell 50 and exit an output surface of the IR photovoltaic cell 50, and can then be incident on an input surface of the photovoltaic cell 40 and enter the photovoltaic cell 40.

The IR photovoltaic cell of the solar panel can be sensitive to at least photons having a wavelength greater than, for example, 1 μm. In an embodiment, the 1R photovoltaic cell is sensitive to photons having a wavelength up to 2500 nm. In another embodiment, the IR photovoltaic cell is sensitive to photons having a wavelength up to about 2000 nm. In a further embodiment, the IR photovoltaic cell is sensitive to photons having a wavelength up to 2000 nm. In yet a further embodiment, the IR photovoltaic cell is sensitive to photons having a wavelength in a range of from about 850 nm to about 2000 nm.

In certain embodiments, the IR photovoltaic cell can include an IR sensitizing layer including quantum dots. The quantum dots can be, for example, PbS or PbSe quantum dots, though embodiments are not limited thereto.

The solar panels of the subject invention can be configured such that incident sunlight is incident upon both the photovoltaic cell and the IR photovoltaic cell and at least a portion of the sunlight is absorbed by the photovoltaic cell and at least a portion of the sunlight is absorbed by the IR photovoltaic cell.

The subject invention also relates to methods of forming a solar panel. In an embodiment, a method of fabricating a solar panel can include: forming a photovoltaic cell, wherein the photovoltaic cell is sensitive to photons having a wavelength in the visible range; forming an infrared photovoltaic cell, wherein the infrared photovoltaic cell is sensitive to photons having a wavelength greater than 1 μm; and coupling the photovoltaic cell and the infrared photovoltaic cell.

The photovoltaic cell and the IR photovoltaic cell can be as described herein with reference to FIGS. 2A and 2B. In many embodiments, the photovoltaic cell is not sensitive to photons having a wavelength greater than 1 μm. For example, the photovoltaic cell can be sensitive to photons in the visible range but not to those having a wavelength greater than 1 μm. In one embodiment, the photovoltaic cell can be sensitive to photons having a wavelength of from about 400 nm to about 850 nm but not sensitive to photons having a wavelength less than about 400 nm or greater than about 850 nm.

The IR photovoltaic cell of the solar panel can be sensitive to at least photons having a wavelength greater than, for example, 1 μm. In an embodiment, the IR photovoltaic cell is sensitive to photons having a wavelength up to 2500 nm. In another embodiment, the IR photovoltaic cell is sensitive to photons having a wavelength up to about 2000 nm. In a further embodiment, the IR photovoltaic cell is sensitive to photons having a wavelength up to 2000 nm. In yet a further embodiment, the IR photovoltaic cell is sensitive to photons having a wavelength in a range of from about 850 nm to about 2000 nm.

In certain embodiments, the IR photovoltaic cell can include an IR sensitizing layer including quantum dots. The quantum dots can be, for example, PbS or PbSe quantum dots, though embodiments are not limited thereto.

The methods of forming a solar panel according to the subject invention can be performed such that the solar panel is configured such that incident sunlight is incident upon both the photovoltaic cell and the IR photovoltaic cell (i.e. at least a portion of the sunlight is absorbed by the photovoltaic cell and at least a portion of the sunlight is absorbed by the IR photovoltaic cell).

In many embodiments, a method of fog wing a solar panel can be performed such that light incident on an input surface of the photovoltaic cell 40 can pass through the photovoltaic cell 40 and exit an output surface of the first photovoltaic cell 40, and can then be incident on an input surface of the IR photovoltaic cell 50 and enter the IR photovoltaic cell 50. In another embodiment, a method of forming a solar panel can be performed such that light incident on an input surface of the IR photovoltaic cell 50 can pass through the IR photovoltaic cell 50 and exit an output surface of the IR photovoltaic cell 50, and can then be incident on an input surface of the photovoltaic cell 40 and enter the photovoltaic cell 40.

In an embodiment, the method of forming a solar panel can include fabricating the IR photovoltaic cell on a glass substrate and then coupling the glass substrate to the photovoltaic cell. The method can also include forming the photovoltaic cell on a glass substrate such that the glass substrate of the IR photovoltaic cell is coupled to the glass substrate of the photovoltaic cell.

In a further embodiment, the IR photovoltaic cell can be coated on an optically clear plastic film, and then the optically clear plastic film can be laminated on the photovoltaic cell.

In yet a further embodiment, the method of forming a solar panel can include forming a solar panel using a structure that positions gas, such as argon gas in between a photovoltaic cell and an IR photovoltaic cell such that the light exiting the photovoltaic cell passes through the gas before entering the IR photovoltaic cell. The gas can be, for example, argon gas, though embodiments are not limited thereto. A specific embodiment can include forming a chamber housing gas (e.g., argon gas). The photovoltaic cell 40 and the IR photovoltaic cell 50 can both be partially, or entirely, positioned within the chamber 70 and/or can form a part of the chamber 70. In certain embodiments, the IR photovoltaic cell can be fabricated on a glass substrate, the photovoltaic cell can be fabricated on a separate glass substrate, the walls of the chamber can be formed, and then the IR photovoltaic cell and the photovoltaic cell can be brought into contact with the chamber walls such that the glass substrates form the top and bottom of the chamber, as depicted in FIG. 2B. The fabrication of IR photodetectors was described in previously-referenced U.S. patent application Ser. No. 13/272,995 (filed Oct. 13, 2011), which claims priority to U.S. Provisional Patent Application Ser. No. 61/416,630 (filed Nov. 23, 2010), and/or was described in U.S. Provisional Patent Application Ser. No. 61/416,630 (filed Nov. 23, 2010), and will now be described again in detail. U.S. patent application Ser. No. 13/272,995 (filed Oct. 13, 2011), which claims priority to U.S. Provisional Patent Application Ser. No. 61/416,630 (filed Nov. 23, 2010), and/or U.S. Provisional Patent Application Ser. No. 61/416,630 (filed Nov. 23, 2010) describe an infrared photodetector with high detectivity for use as a sensor and for use in up-conversion devices. When the dark current is the dominant noise factor, detectivity can be expressed as the following equation (1).

D*=R/(2qJ_{d})^{1/2} (1)

where R is the responsivity, J_{d} is the dark current density, and g is the elementary charge (1.6×10⁻¹⁹ C). To achieve a photodetector with an optimal detectivity, a very low dark current density is required. The photodetectors according to embodiments of the invention include a hole blocking layer (HBL) with a deep highest occupied molecule orbital (HOMO) and an electron blocking layer (EBL) with a high lowest unoccupied molecule orbital (LUMO) where the EBL is situated on the anode facing surface and the HBL is situated on the cathode facing surface of an IR photosensitive layer. The layers can range from about 20 nm to about 500 nm in thickness, and where the overall spacing between electrodes is less than 5 μm. The IR photodetector according to embodiments of the invention allows high detectivity at applied voltages less than 5V.

The IR photosensitive layer can be an organic or organometallic including material or an inorganic material. The material can absorb through a large portion of the IR extending beyond the near IR (700 to 1400 nm), for example to wavelengths up to 1800 nm, 2000, nm, 2500 nm or greater. Exemplary organic or organometallic including materials include: perylene-3,4,9,10-tetracarboxylic-3,4,9,10-dianhydride (PCTDA), tin (II) phthalocyanine (SnPc), SnPc:C₆₀, aluminum phthalocyanine chloride (AlPcCl), AlPcCl:C₆₀, titanyl phthalocyanine (TiOPc), and. TiOPc:C₆₀. Inorganic materials for use as photosensitive layers include: PbSe quantum dots (QDs), PbS QDs, PbSe thin films, PbS thin films, InAs, InGaAs, Si, Ge, and GaAs.

The HBL can be an organic or organometallic including material including, but not limited to: 2,9-Dimethyl-4,7-diphenyl-1,10-phenanthroline (BCP), p-bis(triphenylsilyl)benzene (UGH2), 4,7-diphenyl-1,10-phenanthroline (BPhen), tris-(8-hydroxy quinoline) aluminum (Alq₃), 3,5′-N,N′-dicarbazole-benzene (mCP), C₆₀, and tris[3-(3-pyridyl)-mesityl]borane (3TPYMB). Alternatively, the HBL can be an inorganic material including, but not limited to thin films or nanoparticles of ZnO or TiO₂.

The EBL can be an organic material, for example, but not limited to poly(9,9-dioctyl-fluorene-co-N-(4-butylphenyl)diphenylamine) (TFB), 1,1-bis[(di-4-tolylamino)phenyl]cyclohexane (TAPC), N,N′-diphenyl-N,N′(2-naphthyl)-(1,1′-phenyl)-4,4′-diamine (NPB), N,N′-diphenyl-N,N′-di(m-tolyl) benzidine (TPD), poly-N,N′-bis-4-butylphenyl-N,N′-bis-phenylbenzidine (poly-TPD), or polystyrene-N,N-diphenyl-N,N-bis(4-n-butylphenyl)-(1,10-biphenyl)-4,4-diamine-perfluorocyclobutane (PS-TPD-PFCB).

Photodetectors were prepared having no blocking layer, poly-TPD as an EBL, ZnO nanoparticles as a HBL, and with poly-TPD and ZnO nanoparticles as an EBL and a HBL, respectively, where the IR photosensitive layer included PbSe nanocrystals. The dark current-voltage (J-V) plots for the photodetectors decreased by more than 3 orders of magnitude for that with an EBL and a HBL from the photodetector that is blocking layer free. The photodetector with both blocking layers shows a detectivity of more than 10¹¹ Jones over IR and visible wavelengths smaller than 950 nm.

Inorganic nanoparticle photodetectors were also constructed having no blocking layers and with EBL and HBL layers. The photodetector included various HBLs (BCP, C60, or ZnO), EBLs (TFB or poly-TPD), and PbSe quantum dots included the IR photosensitive layer. Although the magnitude of reduction differs, placement of an EBL and a HBL are placed on the PbSe including photodetector results in a significant reduction of the dark current at low applied voltages.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will he suggested to persons skilled in the art and are to be included within the spirit and purview of this application.

What is claimed is:

1. A solar panel, comprising:
a first photovoltaic cell, wherein the first photovoltaic cell is sensitive to photons having a first one or more wavelengths, wherein the first one or more wavelengths are in a first wavelength range; and
a second photovoltaic cell, wherein the second photovoltaic cell is sensitive to photons having a second one or more wavelengths, wherein the second one or more wavelengths are in a second wavelength range,
wherein at least one of the second one or more wavelengths is not in the first wavelength range;
wherein at least one of the first one or more wavelengths is not in the second wavelength range; and
wherein at least one of the second one or more wavelengths is at least 0.7 μm.

2. The solar panel according to claim 1, wherein the solar panel is configured such that light incident on an input surface of the first photovoltaic cell that passes through the first photovoltaic cell and exits an output surface of the first photovoltaic cell is incident on an input surface of the second photovoltaic cell and enters the second photovoltaic cell.

3. The solar panel according to claim 1, wherein the second photovoltaic cell comprises an infrared sensitizing material layer comprising quantum dots.

4. The solar panel according to claim 3, wherein the quantum dots are PbS quantum dots or PbSe quantum dots.

5. The solar panel according to claim 2, wherein the second photovoltaic cell comprises an infrared sensitizing material layer comprising quantum dots.

6. The solar panel according to claim 5, wherein the quantum dots are PbS quantum dots or PbSe quantum dots.

7. The solar panel according to claim 1, further comprising argon gas, wherein the first photovoltaic cell and the second photovoltaic cell are positioned such that at least a portion of the light passing through the first photovoltaic cell passes through the argon gas prior to entering the second photovoltaic cell.

8. The solar panel according to claim 1, wherein the second photovoltaic cell is sensitive to photons having a wavelength of from 850 nm to about 2000 nm.

9. The solar panel according to claim 8, wherein the second photovoltaic cell is not sensitive to photons having a wavelength of less than 850 nm.

10. The solar panel according to claim 1, wherein the first photovoltaic cell is sensitive to photons having a wavelength of from about 400 nm to 850 nm.

11. The solar panel according to claim 10, wherein the first photovoltaic cell is not sensitive to photons having a wavelength of greater than 850 nm.

12. The solar panel according to claim 1, wherein the first photovoltaic cell is not sensitive to photons having a wavelength of greater than 1 μm.

13. The solar panel according to claim 2, wherein the first photovoltaic cell is not sensitive to photons having a wavelength of greater than 1 μm.

14. The solar panel according to claim 3, wherein the first photovoltaic cell is not sensitive to photons having a wavelength of greater than 1 μm.

15. The solar panel according to claim 4, wherein the first photovoltaic cell is not sensitive to photons having a wavelength of greater than 1 μm.

16. The solar panel according to claim 5, wherein the first photovoltaic cell is not sensitive to photons having a wavelength of greater than 1 μm.

17. The solar panel according to claim 6, wherein the first photovoltaic cell is not sensitive to photons having a wavelength of greater than 1 μm.

18. The solar panel according to claim 1, wherein the second photovoltaic cell comprises a transparent anode and a transparent cathode.

19. The solar panel according to claim 18, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

20. The solar panel according to claim 19, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium:silver).

21. The solar panel according to claim 19, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

22. The solar panel according to claim 18, wherein the transparent anode is transparent to at least a portion of visible light and to at least a portion of infrared light, and wherein the transparent cathode is transparent to at least a portion of visible light and to at least a portion of infrared light.

23. The solar panel according to claim 1, wherein the first photovoltaic cell comprises a transparent anode and a transparent cathode.

24. The solar panel according to claim 23, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

25. The solar panel according to claim 24, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium:silver).

26. The solar panel according to claim 24, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

27. The solar panel according to claim 23, wherein the transparent anode is transparent to at least a portion of visible light and to at least a portion of infrared light, and wherein the transparent cathode is transparent to at least a portion of visible light and to at least a portion of infrared light.

28. The solar panel according to claim 1, wherein the solar panel is configured such that light incident on an input surface of the second photovoltaic cell that passes through the second photovoltaic cell and exits an output surface of the second photovoltaic cell is incident on an input surface of the first photovoltaic cell and enters the first photovoltaic cell.

29. The solar panel according to claim 1, wherein the first photovoltaic cell is a thin film photovoltaic cell.

30. The solar panel according to claim 29, wherein the first photovoltaic cell comprises at least one material selected from the group consisting of CMS, CdTe, a-Si, and poly-Si.

31. The solar panel according to claim 1, wherein the first photovoltaic cell comprises at least one material selected from the group consisting of CIGS, CdTe, a-Si, and poly-Si.

32. The solar panel according to claim 2, wherein the first photovoltaic cell is a thin film photovoltaic cell.

33. The solar panel according to claim 3, wherein the first photovoltaic cell is a thin film photovoltaic cell.

34. The solar panel according to claim 4, wherein the first photovoltaic cell is a thin film photovoltaic cell.

35. The solar panel according to claim 5, wherein the first photovoltaic cell is a thin film photovoltaic cell.

36. The solar panel according to claim 6, wherein the first photovoltaic cell is a thin film photovoltaic cell.

37. A method of fabricating a solar panel, comprising:
forming a first photovoltaic cell, wherein the first photovoltaic cell is sensitive to photons having a first one or more wavelengths, wherein the first one or more wavelengths are in a first wavelength range;
forming a second photovoltaic cell, wherein the second photovoltaic cell is sensitive to photons having a second one or more wavelengths, wherein the second one or more wavelengths are in a second wavelength range; and
coupling the first photovoltaic cell and the second photovoltaic cell,
wherein at least one of the second one or more wavelengths is not in the first wavelength range;
wherein at least one of the first one or more wavelengths is not in the second wavelength range; and
wherein at least one of the second one or more wavelengths is at least 0.7 μm.

38. The method according to claim 37, wherein light incident on an input surface of the first photovoltaic cell that passes through the first photovoltaic cell and exits an output surface of the first photovoltaic cell is incident on an input surface of the second photovoltaic cell and enters the second photovoltaic cell.

39. The method according to claim 37, further comprising:
coating the second photovoltaic cell on an optically clear plastic film; and
laminating the optically clear plastic film on the first photovoltaic cell.

40. The method according to claim 37, further comprising:
forming the second photovoltaic cell on a glass substrate; and
coupling the glass substrate to the first photovoltaic cell.

41. The method according to claim 37, wherein the first photovoltaic cell is a thin film photovoltaic cell, and wherein forming the second photovoltaic cell comprises forming the second photovoltaic cell directly onto the first photovoltaic cell.

42. The method according to claim 37, wherein forming the second photovoltaic cell comprises forming an infrared sensitizing material layer comprising quantum dots.

43. The method according to claim 42, wherein the quantum dots are PbS quantum dots or PbSe quantum dots.

44. The method according to claim 38, wherein forming the second photovoltaic cell comprises forming an infrared sensitizing material layer comprising quantum dots.

45. The method according to claim 44, wherein the quantum dots are PbS quantum dots or PbSe quantum dots.

46. The method according to claim 41, wherein forming the second photovoltaic cell comprises forming an infrared sensitizing material layer comprising quantum dots.

47. The method according to claim 46, wherein the quantum dots are PbS quantum dots or PbSe quantum dots.

48. The method according to claim 37, wherein the second photovoltaic cell is sensitive to photons having a wavelength of from about 850 nm to about 2000 nm.

49. The method according to claim 37, wherein the first photovoltaic cell is not sensitive to photons having a wavelength of greater than 1 μm.

50. The method according to claim 37, wherein the first photovoltaic cell is not sensitive to photons having a wavelength of greater than 1 μm.

51. The method according to claim 38, wherein the first photovoltaic cell is not sensitive to photons having a wavelength of greater than 1 μm.

52. The method according to claim 41, wherein the first photovoltaic cell is not sensitive to photons having a wavelength of greater than 1 μm.

53. The method according to claim 37, wherein light incident on an input surface of the second photovoltaic cell that passes through the second photovoltaic cell and exits an output surface of the second photovoltaic cell is incident on an input surface of the first photovoltaic cell and enters the first photovoltaic cell.

54. The method according to claim 41, wherein the first photovoltaic cell comprises at least one material selected from the group consisting of CIGS, CdTe, a-Si, and poly-Si.

55. The method according to claim 37, wherein the first photovoltaic cell comprises at least one material selected from the group consisting of CIGS, CdTe, a-Si, and poly-Si.

56. The method according to claim 37, wherein forming the second photovoltaic cell comprises forming a transparent anode and a transparent cathode.

57. The method according to claim 56, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

58. The method according to claim 57, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium: silver).

59. The method according to claim 57, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

60. The method according to claim 56, wherein the transparent anode is transparent to at least a portion of visible light and to at least a portion of infrared light, and wherein the transparent cathode is transparent to at least a portion of visible light and to at least a portion of infrared light.

61. The method according to claim 37, wherein forming the first photovoltaic cell comprises forming a transparent anode and a transparent cathode.

62. The method according to claim 61, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

63. The method according to claim 62, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium: silver).

64. The method according to claim 62, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

65. The method according to claim 61, wherein the transparent anode is transparent to at least a portion of visible light and to at least a portion of infrared light, and wherein the transparent cathode is transparent to at least a portion of visible light and to at least a portion of infrared light.

66. A method of capturing and storing solar energy, comprising:
positioning a solar panel such that sunlight is incident on the solar panel, wherein the solar panel comprises:
a first photovoltaic cell, wherein the first photovoltaic cell is sensitive to photons having a first one or more wavelengths, wherein the first one or more wavelengths are in a first wavelength range; and
a second photovoltaic cell, wherein the second photovoltaic cell is sensitive to photons having a second one or more wavelengths, wherein the second one or more wavelengths are in a second wavelength range,
wherein at least one of the second one or more wavelengths is not in the first wavelength range;
wherein at least one of the first one or more wavelengths is not in the second wavelength range; and
wherein at least one of the second one or more wavelengths is at least 0.7 μm.

67. The method according to claim 66, wherein light incident on an input surface of the first photovoltaic cell that passes through the first photovoltaic cell and exits an output surface of the first photovoltaic cell is incident on an input surface of the second photovoltaic cell and enters the second photovoltaic cell.

68. The method according to claim 66, wherein the second photovoltaic cell comprises an infrared sensitizing material layer comprising quantum dots.

69. The method according to claim 68, wherein the quantum dots are PbS quantum dots or PbSe quantum dots.

70. The method according to claim 67, wherein the second photovoltaic cell comprises an infrared sensitizing material layer comprising quantum dots.

71. The method according to claim 70, wherein the quantum dots are PbS quantum dots or PbSe quantum dots.

72. The method according to claim 66, wherein the second photovoltaic cell is sensitive to photons having a wavelength of from about 850 nm to about 2000 nm.

73. The method according to claim 66, wherein light incident on an input surface of the second photovoltaic cell that passes through the second photovoltaic cell and exits an output surface of the second photovoltaic cell is incident on an input surface of the first photovoltaic cell and enters the first photovoltaic cell.

74. The method according to claim 66, wherein the first photovoltaic cell is a thin film photovoltaic cell.

75. The method according to claim 66, wherein the first photovoltaic cell is not sensitive to photons having a wavelength of greater than 1 μm.

76. The method according to claim 67, wherein the first photovoltaic cell is not sensitive to photons having a wavelength of greater than 1 μm.

77. The method according to claim 74, wherein the first photovoltaic cell is not sensitive to photons having a wavelength of greater than 1 μm.

78. The method according to claim 74, wherein the first photovoltaic cell comprises at least one material selected from the group consisting of CIGS, CdTe, a-Si, and poly-Si.

79. The method according to claim 66, wherein the first photovoltaic cell comprises at least one material selected from the group consisting of CIGS, CdTe, a-Si, and poly-Si.

80. The method according to claim 66, wherein the second photovoltaic cell comprises a transparent anode and a transparent cathode.

81. The method according to claim 80, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

82. The method according to claim 81, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium: silver).

83. The method according to claim 81, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

84. The method according to claim 80, wherein the transparent anode is transparent to at least a portion of visible light and to at least a portion of infrared light, and wherein the transparent cathode is transparent to at least a portion of visible light and to at least a portion of infrared light.

85. The method according to claim 66, wherein the first photovoltaic cell comprises a transparent anode and a transparent cathode.

86. The method according to claim 85, wherein the transparent anode comprises at least one material selected from the group consisting of indium tin oxide (ITO), carbon nanotubes (CNTs), indium zinc oxide (IZO), a silver nanowire, and a magnesium:silver/Alq3 stack layer, and wherein the transparent cathode comprises at least one material selected from the group consisting of ITO, CNTs, IZO, a silver nanowire, and a magnesium:silver/Alq3 stack layer.

87. The method according to claim 86, wherein at least one of the transparent anode or the transparent cathode comprises a magnesium:silver/Alq3 stack layer, and wherein a magnesium:silver layer of the magnesium:silver/Alq3 stack layer has a thickness of less than 30 nm, and wherein the magnesium:silver layer has a composition ratio of 10:1 (magnesium: silver).

88. The method according to claim 86, wherein at least one of the transparent anode or the transparent cathode comprises a magnesium:silver/Alq3 stack layer, and wherein an Alq3 layer of the magnesium:silver/Alq3 stack layer has a thickness of from 0 nm to about 200 nm.

89. The method according to claim 85, wherein the transparent anode is transparent to at least a portion of visible light and to at least a portion of infrared light, and wherein the transparent cathode is transparent to at least a portion of visible light and to at least a portion of infrared light.

90. The solar panel according to claim 1, wherein at least one of the second one or more wavelengths is greater than 1 μm.

91. The solar panel according to claim 90, wherein at least one of the second one or more wavelengths is in a range of from 0.7 μm to 1 μm.

92. The method according to claim 37, wherein at least one of the second one or more wavelengths is greater than 1 μm.

93. The solar panel according to claim 92, wherein at least one of the second one or more wavelengths is in a range of from 0.7 μm to 1 μm.

94. The method according to claim 66, wherein at least one of the second one or more wavelengths is greater than 1 μm.

95. The solar panel according to claim 94, wherein at least one of the second one or more wavelengths is in a range of from 0.7 μm to 1 μm.

96. The solar panel according to claim 1, wherein at least one of the second one or more wavelengths is greater than 0.85 μm.

97. The solar panel according to claim 90, wherein at least one of the second one or more wavelengths is in a range of from 0.7 μm to 0.85 μm.

98. The method according to claim 37, wherein at least one of the second one or more wavelengths is greater than 0.85 μm.

99. The solar panel according to claim 92, wherein at least one of the second one or more wavelengths is in a range of from 0.7 μm to 0.85 μm.

100. The method according to claim 66, wherein at least one of the second one or more wavelengths is greater than 0.85 μm.

101. The solar panel according to claim 94, wherein at least one of the second one or more wavelengths is in a range of from 0.7 μm to 0.85 μm.
